(19) United States
(12) Patent Application Publication
(10) Pub. No.: US 2007/0240628 A1
(43) Pub. Date: Oct. 18, 2007

(54) SILICON WAFER

(75) Inventors: Takashi Watanabe, Kanagawa (JP); Hiroyuki Saito, Niigata (JP); Takeshi Senda, Niigata (JP); Koji Izunome, Niigata (JP); Kazuhiko Kashima, Kanagawa (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Toshiba Ceramics Co., Ltd, Shinagawa-ku (JP)

(21) Appl. No.: 11/697,097

(22) Filed: Apr. 5, 2007

(30) Foreign Application Priority Data
Apr. 14, 2006 (JP) 2006-111468
Feb. 27, 2007 (JP) 2007-046603

(51) Int. Cl. C30B 15/14; H01L 21/00; C30B 15/00

(52) U.S. Cl. 117/3; 117/19; 438/13

(57) ABSTRACT

Provided is a silicon wafer suitable for manufacturing a semiconductor device having a shallow junction. A silicon wafer wherein, in a region at a depth of less than 50 μm from a surface, a density of oxygen deposition materials each having a diameter of not less than 10 nm is not more than 1×10⁸/cm³. A silicon wafer for a semiconductor device, which is manufactured by applying heat treatment at a heat treatment temperature of not less than 1000° C. for heat treatment time of not more than 3 msec, wherein, in a region at a depth of less than 50 μm from a surface, a density of oxygen deposition materials each having a diameter of not less than 10 nm is not more than 1×10⁸/cm³.

### CROSS-REFERENCE TO RELATED APPLICATION

This application is based upon and claims the benefit of priority from Japanese Patent Applications No. 2006-111468, filed on Apr. 14, 2006 and No. 2007-046603, filed on Feb. 27, 2007; the entire contents of which are incorporated herein by reference.

### FIELD OF THE INVENTION

The present invention relates to a silicon wafer, and in particular, to a silicon wafer suitable for manufacturing a semiconductor device having a shallow junction and manufactured by application of a high-speed rising/falling temperature heat treatment.

### BACKGROUND OF THE INVENTION

In a single crystal silicon grown by the Czochralski (CZ) method, the following phenomenon is observed. Atomic vacancies agglomerate when the single crystal silicon is cooled, and voids having diameters of about 0.1 to 0.3 μm are formed. Crystal originated particles (COPs) are generated on a surface of a silicon wafer manufactured from the single crystal silicon, and a trouble occurs in operation of a device. For this reason, as a countermeasure against void formation, a method of performing heat treatment at a high temperature of 1000° C. or more in a hydrogen or argon gas atmosphere is employed (see Published Unexamined Japanese Patent Application No. 2003-59932 (JP-A-2003-59932), for example).

In the CZ method, in order to melt and mono-crystallize polysilicon in a quartz crucible, a large amount of oxygen is deposited from quartz constituting the crucible and taken in a silicon crystal as interstitial oxygen, and the oxygen agglutinates in the silicon crystal by heat treatment to obtain an oxygen precipitated material (BMD: Bulk Micro Defect). In device generation before a design rule of 0.25 μm (250 nm), importance is attached to a gettering effect. For this reason, a technique which forms a BMD in a silicon wafer at a high density is used.

Meanwhile, in recent years, wafer heat treatment in device forming steps is changed from a furnace batch processing to a single wafer processing, with an increase in diameter of a wafer. This is because the possibility of occurrence of defects such as slip in a wafer increases in the furnace batch processing when the wafer increases in weight. Furthermore, in order to realize high integration and high speed of a semiconductor device, a source-drain diffusion layer of a transistor is required to be shallowly formed, and heat treatment suitable for the purpose is demanded.

For example, a logic LSI product having a pitch which is half the pitch of a dynamic random access memory (DRAM) and corresponding to the 32-nm generation has a physical gate length of 13 nm. In this logic LSI product, an extension diffusion layer depth of a source-drain diffusion layer of a transistor is required to be 4.5 nm or less, and an extremely shallow junction at a depth of 15 nm or less is required for a contact diffusion layer (for example, International Technology Roadmap for Semiconductors 2005).

In order to form the device having a shallow junction, an impurity must be activated without being diffused as much as possible in heat treatment of a wafer. For this reason, a heat treatment apparatus such as flash lamp annealing which can perform heat treatment at a high temperature for a short time is used.

Naturally, in such a heat treatment apparatus, a temperature rising/falling speed is extremely high, and temperatures on a surface and on a rear surface of a wafer may be different from each other. For this reason, the wafer is considerably stressed in the process to disadvantageously cause wafer cracks. In particular, a silicon wafer having the above highly dense BMD is easily cracked or transformed. Therefore, a semiconductor device having a shallow junction is not easily formed on a silicon wafer by using a high-speed temperature rising/falling temperature heat treatment such as flash lamp annealing.

### SUMMARY OF THE INVENTION

The present invention has been made to solve the above technical problem and to regulate a size and a density of BMDs on a silicon wafer surface. In this manner, a wafer is prevented from being cracked by high-speed rising/falling temperature heat treatment in which temperatures on a surface and a rear surface are different from each other. By doing this, the present invention has as its object to provide a silicon wafer suitable for manufacturing of a semiconductor device having a shallow junction.

In order to achieve the above object, in a silicon wafer according to an embodiment of the present invention, a density of precipitated oxygen each having a diameter of not less than 10 nm is not more than 1×10⁸/cm³ in a region at a depth of less than 50 μm from a surface.

A silicon wafer for a semiconductor device according to another embodiment of the present invention is manufactured by applying heat treatment at a heat treatment temperature of not less than 1000° C. for heat treatment time of not more than 3 msec, wherein, in a region at a depth of less than 50 μm from a surface, a density of precipitated oxygen each having a diameter of not less than 10 nm is not more than 1×10⁸/cm³.

According to the present invention, wafer defects or cracks is suppressed even in a manufacturing process such as high-speed rising/falling temperature heat treatment having a large temperature difference between a surface and a rear surface. Therefore, the present invention can provide a silicon wafer suitable for manufacturing of a semiconductor device having a shallow junction.

### BRIEF DESCRIPTION OF THE DRAWINGS

FIGS. 1A to 1C are pattern diagrams for explaining an operation of a first embodiment;

FIG. 2 is a graph showing BMD density profiles of a silicon wafer according to the first embodiment and a reference silicon wafer;

FIG. 3 is a graph showing an example of a BMD density profile of a silicon wafer according to a second embodiment;

FIG. 4 is a graph showing a relation between a density of BMDs each having a diameter of 5 nm or more to less than 10 nm and a junction leakage in a region at a depth of less than 50 μm from a surface in the second embodiment; AND

FIG. 5 is a diagram for explaining the relation between the density of BMDs each having a diameter of 5 nm or more to less than 10 nm and the junction leakage in the region at a depth of less than 50 μm from the surface in the second embodiment.

### DETAILED DESCRIPTION OF THE EMBODIMENTS

Embodiments of the present invention will be described below in detail with reference to the accompanying drawings.

### First Embodiment

A silicon wafer according to a first embodiment of the present invention has a characteristic feature in which a density of BMDs each having a diameter of 10 nm or more is 1×10⁸/cm³ or less in a region at a depth of less than 50 μm from a surface. In addition, there is a region in which a density of BMDs each having a diameter of 10 nm or more is 1×10⁸/cm³ or more in a region at a depth of 50 μm or more from the surface.

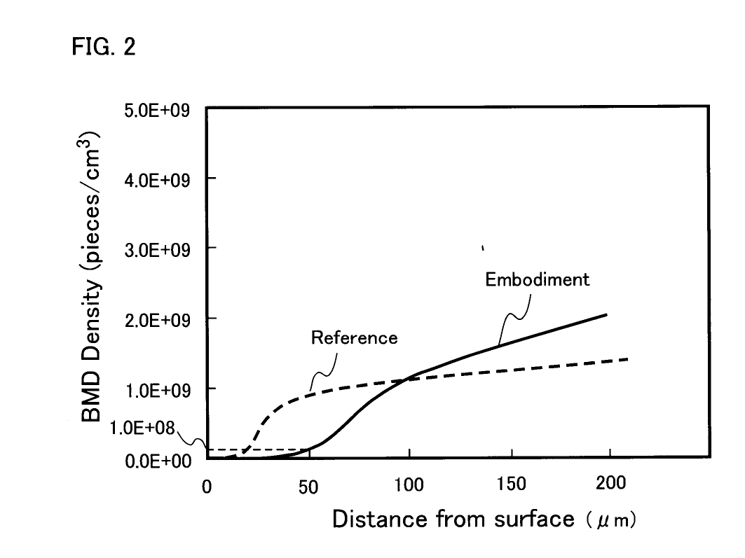

FIG. 2 shows BMD density profiles of the silicon wafer of this embodiment and a reference silicon wafer. The abscissa indicates a distance from the surface of the silicon wafer in a direction of depth, and the ordinate indicates a density of BMDs each having a diameter of 10 nm or more. The BMD density profiles as shown in FIG. 2 can be evaluated by a measuring device using known infrared laser light scattering. As shown in FIG. 2, in the reference silicon wafer, a density of BMDs each having a diameter of 10 nm or more begins to increase in a region shallower than a depth of 20 μm from the surface, and the BMD density is larger than 1×10⁸/cm³ in a region at a distance of about 20 μm from the surface. In contrast to this, in the silicon wafer according to the embodiment, a density of BMDs each having a diameter of 10 nm or more exceeds 1×10⁸/cm³ in a region at a distance of 50 μm or more from the surface. Therefore, in a region at a depth of less than 50 μm from the surface, a density of BMDs each having a diameter of 10 nm or more is 1×10⁸/cm³ or less.

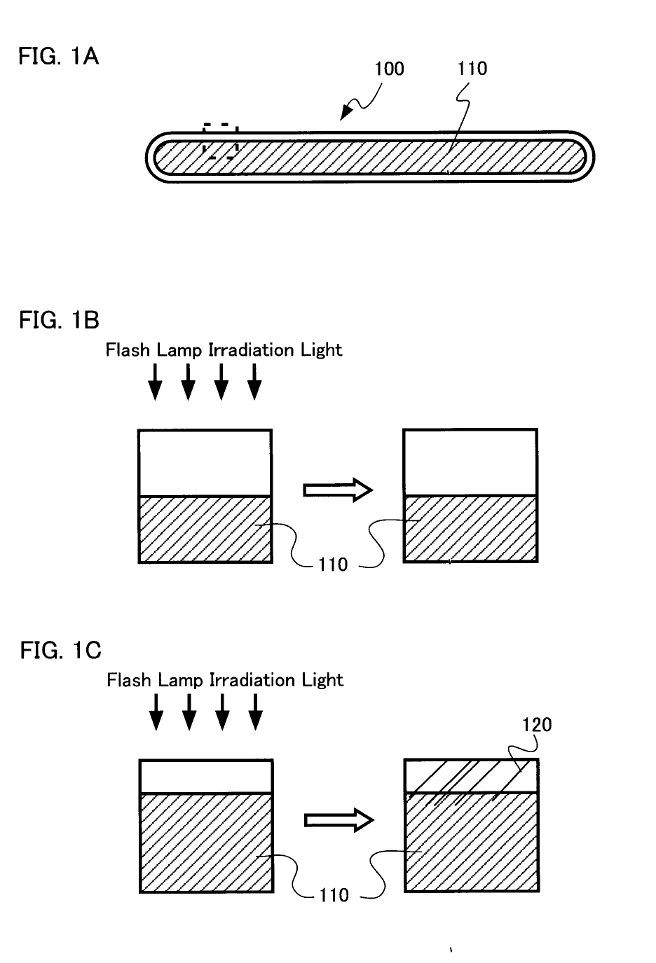

FIGS. 1A to 1C are pattern diagrams for explaining an operation of the embodiment. FIG. 1A is a sectional view of the silicon wafer of the embodiment and the reference silicon wafer, FIG. 1B is a sectional view, showing an operation of the silicon wafer of the embodiment, of a part surrounded by a broken line in FIG. 1B, and FIG. 1C is a sectional view, showing an operation of the reference silicon wafer, of a part surrounded by a broken line in FIG. 1A. As shown in FIG. 1A, a BMD layer 110 having a diameter of 10 μm or more is formed inside a silicon wafer 100 to perform gettering. As shown in FIG. 1C, the reference silicon wafer is subjected to high-speed rising/falling temperature heat treatment at, for example, a temperature of 1000° C. for heating time of 3 msec by using a known flash lamp annealing apparatus. In this case, wafer cracks or dislocated defects 120 occur. In contrast to this, as shown in FIG. 1B, when the high-speed rising/falling temperature heat treatment is performed to the silicon wafer according to the embodiment under the same conditions, wafer cracks or dislocated defects do not occur. Even in heating time of 1 msec in which a temperature rises or falls at a high speed, wafer cracks or dislocated defects do not occur.

In this manner, as described in the embodiment, in a silicon wafer in which a BMD density in a region at a depth of less than 50 μm from the surface of the wafer is reduced, an effect of suppressing an increase in warpage or cracks is obtained even in high-speed rising/falling temperature heat treatment. Accordingly, the wafer can be preferably used as a wafer for high-speed rising/falling temperature heat treatment in which temperatures on a surface and a rear surface of a wafer are different from each other. Therefore, when the silicon wafer according to the embodiment is used, a semiconductor device requiring a shallow junction can be advantageously formed, for example, as in a logic product having a transistor which is manufactured by applying heat treatment at a heat treatment temperature of 1000° C. or more for a heat treatment time of 3 msec or less and which has a physical gate length of about 13 nm. Consequently, the silicon wafer has excellent characteristics for a silicon wafer for a semiconductor device manufactured by application of heat treatment at a heat treatment temperature of 1000° C. or more for a heat treatment time of 3 msec or less.

The reason why the above operation and effect are obtained by the present embodiment will be described below.

A silicon wafer in which a density of BMDs each having a diameter of 10 nm or more exceeds 1×10⁸/cm³ in a region at a depth of less the 50 μm from a surface is easily cracked in high-speed rising/falling temperature heat treatment such as flash lamp annealing in which temperatures on the surface and the rear surface of the wafer are different from each other. When the present inventors analyze differences between a wafer which can be cracked and a wafer which cannot be cracked, even the wafer which cannot be cracked may be plastically deformed and may increase in warpage. This is because heat stress caused by the high-speed rising/falling temperature heat treatment acts on BMD which is a discontinuous point in a wafer crystal to generate dislocation (slip), and the stress may be moderated by the dislocation not to crack the wafer. In fact, even in a wafer which is not cracked, a large number of cracks caused along growing stripes of a single crystal are observed by X-ray topography (XRT).

Even in a warped wafer, occurrence of dislocation is not observed in a region at a depth of 50 μm or more from the surface of the wafer. For this reason, BMD having a diameter of 10 nm or more and being present in a region at a depth of less than 50 μm from the surface of the wafer may serve as a source of dislocation or cracks. Therefore, as described in the embodiment, when the density of BMDs each having a diameter of 10 nm or more and being present in a region at a depth of less than 50 μm from the surface of the wafer is reduced, the above effect which suppresses occurrence of defects, increase in warpage, and cracks in the wafer may be achieved.

In the embodiment, the reason why a distribution and a density of only BMDs each having a diameter of 10 nm or more are limited is that occurrence of defects, an increase in warpage, and cracks in the wafer do not depend on the presence of BMDs each having a diameter of less than 10 nm. In addition, the depth from the surface is limited to less than 50 μm because even when BMDs each having a diameter of 10 nm or more are present at a density of 1×10⁸/cm³ in the region at a depth of 50 μm or more, occurrence of defects, an increase in warpage, and cracks in the wafer are not observed. In contrast to this, when BMDs each having a diameter of 10 nm or more are present at a density of 1×10⁸/cm³ or more in a region shallower than a depth of 50 μm, occurrence of defects, an increase in warpage, and cracks in the wafer become marked.

Now, a method of manufacturing a silicon wafer according to the embodiment showing a BMD profile in FIG. 2 will be described below. The silicon wafer according to the embodiment can be manufactured such that heat treatment is performed at 1200° C. for two hours in an oxygen atmosphere to a silicon wafer having an oxygen concentration of 1.1 to 1.5×10¹⁸ atoms/cm³ or less and having a diameter of 200 mm.

When the silicon wafer according to the embodiment is used in manufacturing of a semiconductor device manufactured by applying, especially, high-speed rising/falling temperature heat treatment such as flash lamp annealing at a heat treatment temperature of 1000° C. or more for a heat treatment time of 3 msec or less, the operation and effect of the silicon wafer notably appear. However, for example, even in another high-speed rising/falling temperature heat treatment such as rapid thermal processing (RTP) which is performed by using a halogen lamp as a heat source at a rising/falling temperature speed of about 100 to 300° C./sec, occurrence of defects, an increase in warpage, and cracks in a wafer can be suppressed as is apparent from a principle of appearance of the operation and effect.

In the embodiment, it is assumed that a region in which a density of precipitated oxygen (BMD) each having a diameter of 10 nm or more is 1×10⁸/cm³ or more is present in a region having a distance of 50 μm or more from a surface. In the steps of manufacturing a device, a sufficient amount of BMD is desirably present in a deep portion of the wafer in terms of gettering of metal impurities such as Fe and Ni and prevention of deterioration of insulating film characteristics and junction leakage characteristics on the device. However, in terms of suppression of occurrence of defects, an increase in warpage, and cracks in high-speed rising/falling temperature heat treatment, a region in which a BMD density is 1×10⁸/cm³ or more is not necessarily present at a depth of 50 μm or more.

In the embodiment, in particular, the silicon wafer having a diameter of 200 mm has been exemplified. However, the present invention is effective in a large-diameter silicon wafer having a diameter of 200 mm or more.

In the embodiment, a silicon wafer is manufactured by heat treatment performed at 1200° C. for two hours in a hydrogen atmosphere. However, in manufacturing of a silicon wafer characterized in that a density of precipitated oxygen having a diameter of 10 nm or more is 1×10⁸/cm³ or less in a region at a depth of less than 50 μm from a surface, the manufacturing conditions are not limited to the above conditions. More specifically, heat treatment at 100° C. or more to 1200° C. or less for appropriate time in a gas atmosphere containing at least one of hydrogen and argon to make it possible to manufacture a silicon wafer in which sizes and a density of BMDs are regulated as described above.

### Second Embodiment

A silicon wafer according to a second embodiment of the present invention is the same as that of the first embodiment except that a density of precipitated oxygen each having a diameter of 5 nm or more to less than 10 nm is 1×10⁹/cm³ or more to 9×10⁹/cm³ or less in a region at a depth of less than 50 μm from a surface. Therefore, a description of the silicon wafer overlaps the description of the first embodiment is omitted.

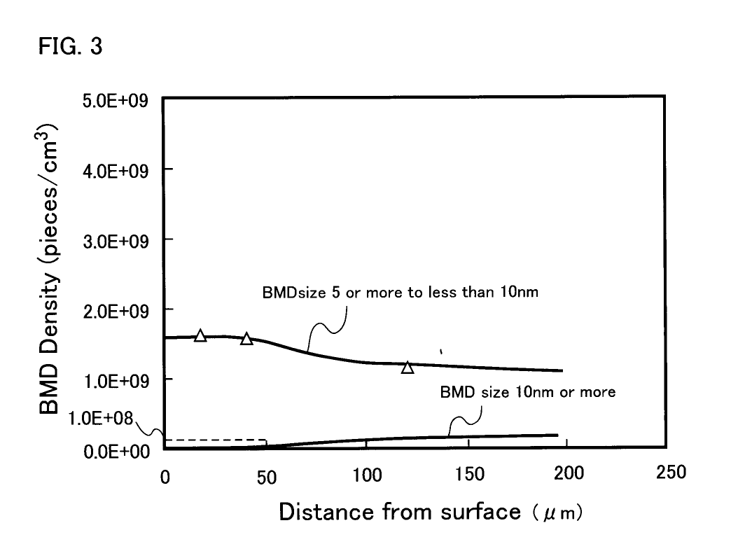

FIG. 3 shows an example of a BMD density profile of the silicon wafer according to the embodiment. The abscissa indicates a distance from the surface of the silicon wafer in a direction of depth, and the ordinate indicates a BMD density. With respect to BMDs each having a diameter of 10 nm or more, the BMD density profiles as shown in FIG. 3 can be evaluated by a measuring device using known infrared laser light scattering. BMDs each having a diameter of 5 nm or more to less than 10 nm can be measured by a transmission electron microscope (TEM). Triangle marks in FIG. 3 indicate actual measurement values.

As shown in FIG. 3, in the silicon wafer according to the embodiment, a region at a distance of 50 μm or more from the surface includes a region in which a density of BMDs each having a diameter of 10 nm or more is 1×10⁸/cm³ or more. In a region at a depth of less than 50 μm from the surface, a density of oxygen deposition materials (BMDs) each having a diameter of 5 nm or more to less than 10 nm is about 1.6×10⁹/cm³, i.e., falls within the range of 1×10⁹/cm³ or more to 9×10⁹/cm³ or less.

The present inventors continuously performed an examination by using the silicon wafer of the first embodiment highly resistant to high-speed rising/falling temperature heat treatment. Then, it has been found that junction leakage currents of p-n junctions formed by using high-speed rising/falling temperature heat treatment fluctuate on wafers in each of which a density of BMDs each having a diameter of 10 nm or more is 1×10⁸/cm³ or less in a region at a depth of less than 50 μm from the surface and a region at a distance of 50 μm or more from the surface includes a region in which a density of BMDs each having a diameter of 10 nm or more is 1×10⁸/cm³.

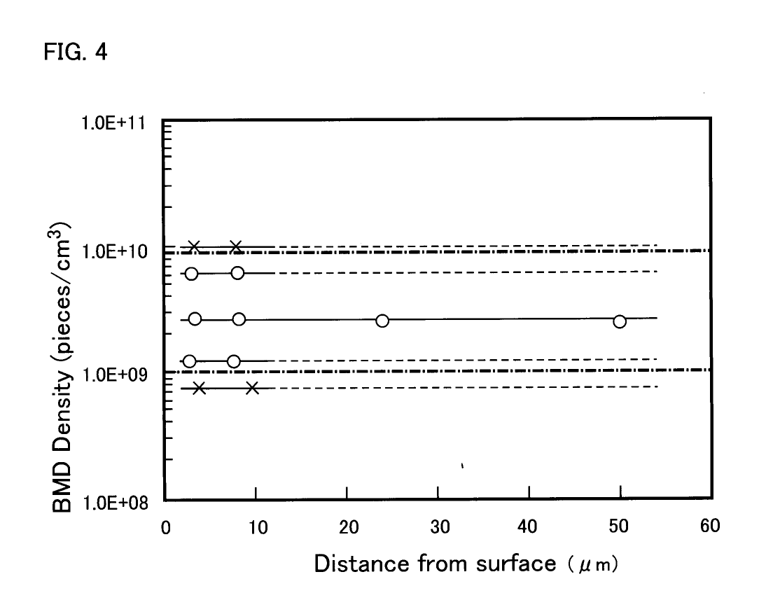

Therefore, the present inventors performed an examination with giving attention to a density of BMDs each having a diameter of 5 nm or more to less than 10 nm in a region at a depth of less than 50 μm from the surface. The obtained results are shown in FIG. 4. The abscissa indicates a distance from the surface in a direction of depth, and the ordinate indicates a density of BMDs each having a diameter of 5 nm or more to less than 10 nm. A solid line and a broken line in FIG. 4 indicate BMD density profiles of a plurality of silicon wafers. Open circles and x marks in FIG. 4 indicate actual measurement points of the BMD densities by a TEM. It has been found that even though a BMD density in a region at a depth of less than 50 μm from the surface is less than 1×10⁹/cm³ or larger than 9×10⁹/cm³, a junction leakage current of a p-n junction increases. More specifically, the junction leakage current exhibits a minimum value in a range of a BMD density of 1×10⁹/cm³ or more to 9×10⁹.cm³ or less between long dashed and short dashed lines. In a silicon wafer having a BMD density profile the actual measurement value of which is indicated by an open circle, junction leakage current specifications corresponding to that of a logic LSI product having a physical gate length of about 13 nm may be realized. On the other hand, in a silicon wafer having a BMD density profile the actual measurement point of which is indicated by an x mark, a junction leakage current becomes excessively large. For this reason, an yield of microscopic logic LSI products manufactured on the wafer and each having a MOSFET having a physical gate length of about 13 nm is supposed to decrease.

As described above, according to the silicon wafer of the embodiment, as in the first embodiment, an effect of suppressing occurrence of defects, an increase in warpage, and cracks in the wafer can be obtained even though high-speed rising-falling temperature heat treatment is used to form a shallow junction. Furthermore, an operation of suppressing junction leakage makes it possible to realize specifications required by a microscopic logic LSI product. Therefore, semiconductor devices such as microscopic logic LSIs having shallow junctions can be advantageously manufactured at a high yield.

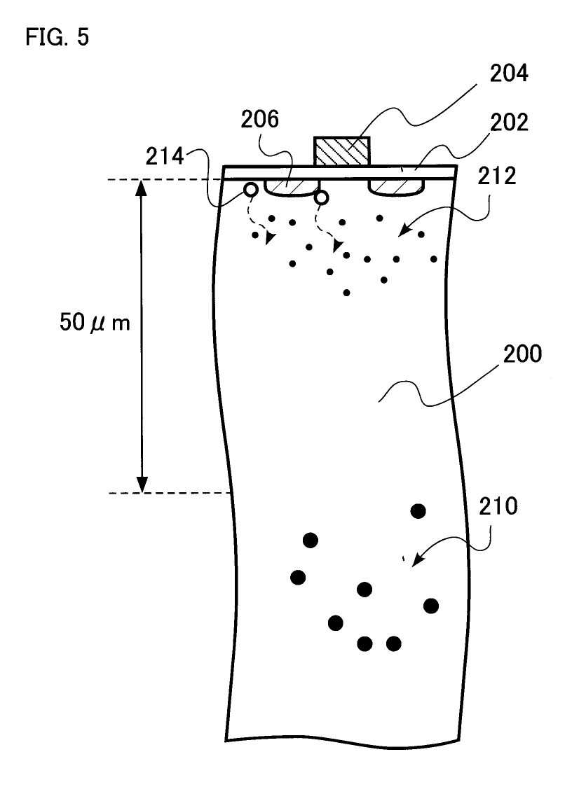

The reason why junction leakage depends on a density of BMDs each having a diameter of 5 nm or more to less than 10 nm in a region at a depth of less than 50 μm from the surface will be described below by using a pattern diagram in FIG. 5. In FIG. 5, formed on a silicon wafer 200 is a MOSFET constituted by a channel region in a gate insulating film 202, a gate electrode 203, a source-drain diffusion layer 206, and a silicon substrate.

Assume that, in a heat treatment process corresponding to that of a microscopic logic LSI, BMDs 210 each having a diameter of 10 nm or more and indicated by large black circles in FIG. 5 are distributed in a region at a depth of 50 μm or more from the surface. Even in this case, a metal contaminant 214 such as Fe or Ni indicated by open circles in FIG. 5 cannot be gettered if a density of BMDs 212 each having a diameter of 5 nm or more to less than 10 nm and indicated by small black circles is small. More specifically, on demand to realize a shallow junction, shortening of time and decrease in temperature are performed in a heat treatment process for a microscopic logic LSI as much as possible not to diffuse an impurity in a source-drain region. Therefore, the metal impurity 214 entering the wafer from the surface thereof is not easily diffused to a deep portion at a depth of 50 μm or more from the surface. For this reason, a gettering effect obtained by the BMDs 210 each having a diameter of 10 nm or more becomes small. As a consequence, reduction in junction leakage caused by the metal impurity 214 as being a generation center becomes difficult. On the other hand, in a heat treatment process for a product having a relatively large design rule, the metal impurity 214 near a device is diffused to a deep portion at a depth of 50 μm or more from the surface to perform gettering, so that junction leakage can be sufficiently reduced, because of the high temperature and long heat treatment. As described in the embodiment, when a density of BMDs 212 each having a diameter of 5 nm or more to less than 10 nm in a shallow region at a depth of less than 50 μm from the surface is controlled to be equal to or higher than a certain level, the metal impurity can be gettered by the BMDs 212 even in a heat treatment process corresponding to that of a microscopic logic LSI. Therefore, even though heat treatment is suppressed, junction leakage can be reduced to be set in required specifications.

As a matter of course, in contrast to this, when a density of the BMDs 212 each having a diameter of 5 nm or more to less than 10 nm and indicated by small black circles in FIG. 5 in a region at a depth of less than 50 μm from the surface is excessively high, junction leakage caused by the BMDs increase. Therefore, when the BMD density increases to a certain level or more, a junction leakage reducing effect obtained by the gettering effect of the metal impurity 214 by the BMDs 212 in the shallow region is canceled out.

Therefore, in order to suppress junction leakage of a semiconductor device having a shallow junction and achieve desired specifications, a density of oxygen deposition materials each having a diameter of 5 nm or more to less than 10 nm is desirably 1×10⁹/cm³ or more to 9×10⁹/cm³ or less in a region at a depth of less than 50 μm from the surface, as in the silicon wafer according to the embodiment.

An example of a method of manufacturing a silicon wafer according to the embodiment the BMD profile of which is shown in FIG. 4 will be described below. For example, first heat treatment is performed at a temperature rising rate of 5° C./min and the highest temperature of 1250° C. for holding time of 1 hour to a silicon wafer having an oxygen concentration of 1.1 to 1.5×10¹⁸ atoms/cm³ or less and a diameter of 200 mm to temporarily heat the silicon wafer to 400° C. Thereafter, second heat treatment is performed at a temperature rising rate of 1° C./min for holding time of 15 min at the highest temperature in a region at 450° C. to 1000° C. In this case, in the first heat treatment, a deep DZ (Denuded Zone: nondefective) region is formed, and BMDs are formed in the deep region at a depth of 50 μm or more from the surface. In the second heat treatment, formation of a new core and growth of BMDs are promoted in the DZ region. However, as described in the above example, the maximum temperature is desirably limited to 1000° C. or less not to cause the sizes of BMDs formed by the second heat treatment to exceed a diameter range of 5 nm or more to less than 10 nm.

The embodiments of the present invention have been described above with reference to the concrete examples. In the description of the embodiments, a description of parts and the like which are not directly required for the explanation of the present invention is omitted in a silicon wafer and a method of manufacturing a silicon wafer. However, elements related to a necessary silicon wafer, a method of manufacturing a silicon wafer, a silicon wafer for a semiconductor device, and the like can be appropriately selected and used. In addition, all silicon wafers and all silicon wafers for semiconductor devices which include the elements of the present invention and the settings of which can be appropriately changed by a person skilled in the art are included in the spirit and scope of the invention.

What is claimed is:

1. A silicon wafer wherein
in a region at a depth of less than 50 μm from a surface, a density of precipitated oxygen each having a diameter of not less than 10 nm is not more than 1×10⁸/cm³.

2. The silicon wafer according to claim 1, wherein
in the region at the depth of less than 50 μm from the surface, a density of precipitated oxygen each having a diameter of not less than 5 nm to less than 10 nm is not less than 1×10⁹/cm³ to not more than 9×10⁹/cm³.

3. The silicon wafer according to claim 1, wherein
in the region at the depth of not less than 50 μm from the surface, a region in which a density of precipitated oxygen each having a diameter of not less than 10 nm is not less than 1×10⁸/cm³.

4. The silicon wafer according to claim 2, wherein
in the region at the depth of not less than 50 μm from the surface, a region in which a density of oxygen deposition materials each having a diameter of not less than 10 nm is not less than 1×10⁸/cm³.

5. A silicon wafer for a semiconductor device, which is manufactured by applying heat treatment at a heat treatment temperature of not less than 1000° C. for heat treatment time of not more than 3 msec, wherein
in a region at a depth of less than 50 μm from a surface, a density of oxygen deposition materials each having a diameter of not less than 10 nm is not more than 1×10⁸/cm³.

6. The silicon wafer according to claim 5, wherein
in the region at the depth of less than 50 μm from the surface, a density of oxygen deposition materials each having a diameter of not less than 5 nm to less than 10 nm is not less than 1×10⁹/cm³ to not more than 9×10⁹/cm³.

7. The silicon wafer according to claim 5, wherein
in the region at the depth of not less than 50 μm from the surface, a region in which a density of oxygen deposition materials each having a diameter of not less than 10 nm is not less than 1×10⁸/cm³.

8. The silicon wafer according to claim 6, wherein
in the region at the depth of not less than 50 μm from the surface, a region in which a density of oxygen deposition materials each having a diameter of not less than 10 nm is not less than 1×10⁸/cm³.
